(19) United States
(12) Patent Application Publication
(10) Pub. No.: US 2022/0410339 A1
(43) Pub. Date: Dec. 29, 2022

(54) POLISHING PAD WITH PROTRUDED POLISHING STRUCTURES, SYSTEM FOR MANUFACTURING THE SAME, AND METHOD FOR MANUFACTURING THE SAME

(71) Applicant: Smart Pad LLC, Rexford, NY (US)

(72) Inventor: Sunghoon LEE, Rexford, NY (US)

(21) Appl. No.: 17/733,951

(22) Filed: Apr. 29, 2022

Related U.S. Application Data
(60) Provisional application No. 63/213,925, filed on Jun. 23, 2021.

(51) Int. Cl. B24B 37/26; B24B 37/24; B24D 18/00

(52) U.S. Cl. CPC B24B 37/26; B24B 37/24; B24D 18/0009; B24D 18/009

(57) ABSTRACT

A method for fabricating a polishing pad including a plurality of polishing structures includes providing a mold having a top surface and a bottom surface, the mold including a plurality of recesses that correspond to polishing structures formed on the top surface thereof; dispensing a polymer mix on the mold and allowing the polymer mix to fill the plurality of recesses to be formed as the polishing structures; laminating a base film on the top surface of the mold; curing the polymer mix to allow the polymer mix to adhere to the base film and to form the polishing structures on the base film; and demolding the base film and the polishing structures from the mold to obtain a polishing pad sheet. Subsequently, the polishing pad sheet is cut into a plurality of polishing pads.

### CROSS-REFERENCE TO RELATED APPLICATION

The present application claims priority from Provisional Application No. 63/213,925 filed on Jun. 23, 2021, which application is incorporated herein by reference in its entirety.

### TECHNICAL FIELD

The present disclosure relates to polishing pads, and more particularly, to chemical-mechanical polishing pads with protruded polishing structures for improved thermal stability and more consistent polishing, and systems and methods for manufacturing the same.

### RELATED ART

Chemical-mechanical polishing (CMP) is used in semiconductor fabrication processes for smoothing uneven or undulated patterns on the wafer surface. The CMP process flattens the surface of a wafer or a manufacturing article on the atomic level, while minimizing surface defects, using interactions of frictional and chemical energies. Polishing is achieved by generating a relative motion between a manufacturing article and a polishing pad while pressing down the manufacturing article on the polishing pad and supplying a polishing slurry. The CMP process is used in the ultra large scale integration (VLSI) manufacturing and considered an essential technology for smoothing transistor elements or interlayer insulations of multi-layer interconnects, fabricating tungsten or copper interconnects, and the like.

FIG. 1 shows a typical setup for the CMP process. Referring to FIG. 1, the CMP process includes attaching a polishing pad 1 on a platen 2, supplying a polishing slurry 3 on the polishing pad 1, pressing a manufacturing article 4 (e.g., a wafer) against the polishing pad 1, and generating a relative motion between the polishing pad 1 and the manufacturing article 4.

The polishing pad is a tool that is used during the CMP process and is formed in a thin planar shape and mainly made of polymer materials. To control the polishing rate uniformly across the wafer, both the polishing pad and the wafer are rotated as shown in FIG. 1 in a state where the polishing pad and the wafer are pressed against each other. In particular, the polishing rate may be determined by a product of polishing pressure and a relative velocity between the polishing pad and the wafer (i.e., polishing pressure×relative velocity). In other words, once the polishing tool and the manufacturing article are given, the polishing rate is determined by the pressure and the relative velocity. The requirements for the CMP process include polishing stability and repeatability. Factors that impact the polishing stability include variations of frictional heat and surface condition.

The frictional heat generated from the frictional abrasion has a significant impact on the polishing. For example, even when the polishing pressure and the relative velocity are constant, the amount of frictional heating can vary depending on the chemical, mechanical, and/or thermal properties of the polishing slurry and the pad. Accordingly, the frictional heat impacts the polishing rate. Therefore, although an ability to tightly control the pressure and the relative velocity generally improves the polishing stability or repeatability, a complex matrix of variations in consumable parts and polishing conditions even during the process significantly impacts the polishing stability. Therefore, controlling the complex factors in the CMP process with a tight precision is critical for a stable and repeatable polishing process.

However, as the polishing process proceeds, the frictional heat from the polishing process accumulates in the equipment, and the process temperature changes, causing degradation of the polishing stability and repeatability. As such, control of the frictional heat is required to maintain the polishing stability. Since conventional polishing pads in the related art are made of polymer layers with poor heat transfer characteristics, improvement is sought.

In addition, another factor that degrades the polishing stability is the consistency of the pad surface. More specifically, the polishing rates are proportional to the surface roughness of the pad. However, the roughness of the polishing surface varies over time. To overcome this problem and to restore the surface roughness, the polishing pads are typically scrubbed with a roughening tool such as a conditioning disc 5 (shown in FIG. 1) that includes diamond particles coated thereon. Since numerous factors such as the size and distribution of the diamond particles, pressure, conditioning method, and the stability of the conditioning tool govern the conditioning results, it is difficult to consistently maintain the surface condition of the polishing pad by roughening. As a result, the surface roughness of the conventional polishing pads in the related art is inconsistent and difficult to control.

### SUMMARY

The present disclosure provides design and manufacturing of polishing pads, which are used as a polishing tool in the semiconductor or optical components manufacturing during, for example, chemical-mechanical polishing, mechano-chemical polishing, and tribochemical polishing processes. The polishing pads according to the present disclosure may provide improved thermal stability and may maintain more consistent surface roughness of the polishing surface. Further, the systems and methods for manufacturing according to the present disclosure may provide high-throughput, improved quality-control, and economical manufacturing of the polishing pads.

An aspect of the present disclosure provides a method for fabricating a polishing pad including a plurality of polishing structures. The method may include providing a mold having a top surface and a bottom surface, wherein a plurality of recesses that correspond to the polishing structures are formed on the top surface of the mold; dispensing a polymer mix on the mold and allowing the polymer mix to fill the plurality of recesses to be formed as the polishing structures; laminating a base film on the top surface of the mold; curing the polymer mix to allow the polymer mix to adhere to the base film and to form the polishing structures on the base film; and demolding the base film and the polishing structures from the mold to obtain a polishing pad sheet.

One or more of the following features can be included individually or in any combination thereof.

The base film may be supplied from a roll by being unwound therefrom. Subsequent to the laminating or the curing, the base film may be cut along a direction parallel to a rotational axis of the roll of the base film. In some embodiments, the polymer mix may be dispensed on the mold by a dispenser that moves linearly along a direction parallel to a rotational axis of the laminating roller unit.

The laminating may be performed with a laminating roller unit. The laminating roller unit may move the mold at a speed between about 0.1 feet/min and about 20 feet/min, and the laminating roller unit may press the base film and the mold at a pressure between 0 and about 20 psi.

In some embodiments, the laminating roller unit may include a first roller and a second roller. In such embodiments, the mold, the polymer mix, and the base film may be press-rolled between the first roller and the second roller.

In some embodiments, the laminating and the curing may be performed with the laminating roller unit, and the laminating roller unit may be heated to a predetermined temperature. By way of example, the predetermined temperature may be between about 20° C. and about 120° C.

Prior to the laminating, plasma-treating may be applied to a surface of the base film that is laminated to the mold to remove impurities on the surface and/or to increase a surface energy. During the curing after the lamination, the base film may be pressed against the mold. The curing may include pressing the base film against the mold in a temperature-controlled chamber. By way of example, the temperature-controlled chamber may be maintained at a temperature between about 20° C. and about 120° C. in an air or inert gas environment.

In some embodiments, during the laminating, the mold may be press-rolled through the laminating roller unit while the mold is inclined with respect to a horizontal plane by a predetermined tilting angle. The predetermined tilting angle may be between about 10° and about 90°.

Subsequent to the demolding, the method may also include further curing at a temperature between about 20° C. and about 120° C. in an air or inert gas environment. Further, the method may include cutting the polishing pad sheet into a plurality of polishing pads.

The mold may be fabricated using a master mold. In some embodiments, a material for the mold may include silicone. In some other embodiments, a material for the mold may include nickel. The master mold may be fabricated using (a) photolithography on a dry film resist disposed on a planar substrate; (b) electrical discharge machining (EDM); (c) photolithography and wet etching; (d) 3-D printing; (e) laser machining; or any combination thereof.

In some embodiments, the base film may include one or more material selected from the group consisting of polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, and p-phenylene sulfide.

The polymer mix may include a pre-polymer and a curing agent. The pre-polymer may include one or more selected from the group consisting of polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, and p-phenylene sulfide. The polymer mix may further include one or more additives. By way of example, the one or more additives may include Teflon, graphene, carbon nanoparticles, or any combination thereof. Further, the plurality of polishing structures may exhibit a greater hardness than the base film.

In a related aspect of the present disclosure, a method for fabricating a polishing pad including a plurality of polishing structures may include unwinding a base film from a first roll; dispensing a polymer mix on a surface of the base film; rolling the base film and the polymer mix through a molding roller unit to imprint polishing structures on the polymer mix; and winding the base film formed with the polishing structures onto a second roll. In particular, the molding roller unit may include a plurality of recesses that correspond to the polishing structures.

One or more of the following features can be included individually or in any combination thereof.

In some embodiments, the molding roller unit may include a first roller and a second roller. In such embodiments, one of the first roller or the second roller may include the plurality of recesses that correspond to the polishing structures, and the base film and the polymer mix may be press-rolled between the first roller and the second roller.

In some embodiments, the molding roller unit may include a molding roller including the plurality of recesses that correspond to the polishing structures; and a tensioning unit configured to press the base film onto the molding roller. The tensioning unit may include an upstream roller disposed between the molding roller and the first roll; and a downstream roller disposed between the molding roller and the second roll. In such embodiments, the upstream roller and the downstream roller may be disposed to contact a back surface of the base film where no polymer mix is coated, and the molding roller may contact the surface of the base film where the polymer mix is coated. Further, speeds of the upstream roller and the downstream roller may be controlled to cause the base film to be pressed against the molding roller by a tension created due to a speed difference between the upstream roller and the downstream roller.

The plurality of recesses may be formed on the molding roller unit by laser engraving. In some embodiments, the molding roller unit may further include one or more heated rollers; a heated sleeve; or both, which are disposed around at least a part of a periphery of the molding roller. The molding roller unit may be heated to a predetermined temperature. By way of example, the predetermined temperature may be between about 20° C. and about 120° C.

In some embodiments, the method may further include curing the second roll at a temperature between about 20° C. and about 120° C. in an air or inert gas environment. The method may further include unwinding the base film formed with the polishing structures from the second roll; and cutting the unwound base film into a plurality of polishing pads.

The plurality of polishing structures may have a greater hardness than the base film. The base film may include one or more material selected from the group consisting of polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, and p-phenylene sulfide.

The polymer mix may include a pre-polymer and a curing agent. The pre-polymer may include one or more selected from the group consisting of polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, and p-phenylene sulfide. Further, the polymer mix may further include one or more additives. By way of example, the one or more additives may include Teflon, graphene, carbon nanoparticles, or any combination thereof.

In a related aspect of the present disclosure, a system for fabricating a polishing pad including a plurality of polishing structures may include a first roll from which a base film is unwound; a dispenser that dispenses a polymer mix on a surface of the base film being unwound from the first roll; a molding roller unit that press-rolls the base film and the polymer mix therebetween to imprint polishing structures on the polymer mix; and a second roll onto which the base film formed with the polishing structures is wound. The molding roller unit may include a plurality of recesses that correspond to the polishing structures.

One or more of the following features can be included individually or in any combination thereof.

In some embodiments, the molding roller unit may include a first roller and a second roller, and one of the first roller or the second roller may include the plurality of recesses that correspond to the polishing structures. In such embodiments, the base film and the polymer mix may be press-rolled between the first roller and the second roller.

In some embodiments, the molding roller unit may include a molding roller including the plurality of recesses that correspond to the polishing structures; and a tensioning unit configured to press the base film onto the molding roller.

In an aspect of the present disclosure, a method for fabricating a polishing pad including a plurality of polishing structures may include transferring a polymer mix from a reservoir to a first roller; transferring the polymer mix from the first roller to a second roller; and transferring the polymer mix from the second roller onto a base film. As such, the polymer mix may be printed on the base film, thereby forming the plurality of polishing structures.

One or more of the following features can be included individually or in any combinations thereof.

In some embodiments, the base film may be pressed against the second roller via a third roller.

In some embodiments, the second roller may include a plurality of cells on a peripheral surface thereof to retain a controlled amount of the polymer mix therein. Further, excess amount of the polymer mix may be removed from the second roller using a blade provided adjacent to the second roller.

In some embodiments, the base film may include a plurality of microscale features that forms the plurality of polishing structures when coated with the polymer mix.

In some embodiments, the method may further include a first curing step using UV light and/or heat. The method may further include a second curing step performed at a temperature between about 20° C. and about 120° C.

In some embodiments, the method may include transferring the polymer mix from the second roller onto a fourth roller; and transferring the polymer mix from the fourth roller onto the base film. In some such embodiments, the fourth roller may include a plurality of microscale features, which correspond to the plurality of polishing structures to be formed on the polishing pad.

In a related aspect of the present disclosure, a system for fabricating a polishing pad including a plurality of polishing structures may include a first roller, a portion of which is immersed in a reservoir of a polymer mix to transfer the polymer mix from the reservoir; a second roller disposed in contact with the first roller to transfer the polymer mix from the first roller; and a third roller that rolls a base film such that the polymer mix is transferred onto the base film. Accordingly, the polymer mix that is transferred on to the base film may form the plurality of polishing structures.

One or more of the following features can be included individually or in any combination thereof.

In some embodiments, a peripheral surface of the second roller may include a plurality of cells to retain the polymer mix therein. The second roller may further include a blade to remove excess amount of the polymer mix from the peripheral surface of the second roller.

In some embodiments, the system may further include a fourth roller disposed between the second roller and the third roller to transfer the polymer mix from the second roller onto the fourth roller and then onto the base film, and the fourth roller may include a plurality of microscale features, which correspond to the plurality of polishing structures to be formed on the polishing pad.

Notably, the present disclosure is not limited to the combination of the elements as listed above and may be assembled in any combination of the elements as described herein. Other aspects of the disclosure are disclosed herein.

### BRIEF DESCRIPTION OF THE DRAWINGS

A brief description of each drawing is provided to more sufficiently understand drawings used in the detailed description of the present disclosure.

FIG. 1 shows a general setup of chemical-mechanical polishing process;

FIG. 2 shows a polishing pad according to an exemplary embodiment of the present disclosure;

FIG. 3 depicts an individual polishing structure of a polishing pad according to exemplary embodiments of the present disclosure;

FIG. 4A schematically shows a system for manufacturing a polishing pad according to an exemplary embodiment of the present disclosure;

FIG. 4B schematically shows an example of a nozzle for the system shown in FIG. 4A;

FIG. 4C schematically shows another example of a nozzle for the system shown in FIG. 4A;

FIG. 5 illustrates polymer mix dispensing and filling a plurality of recesses on a mold, and laminating a base film using a laminating roller in a polishing pad manufacturing process according to an exemplary embodiment of the present disclosure;

FIG. 6 illustrates manufacturing a polishing pad according to an exemplary embodiment of the present disclosure, in which the mold is press-rolled through a laminating roller unit while the mold is inclined with respect to a horizontal plane;

FIG. 7 schematically shows a manufacturing process of the mold according to an exemplary embodiment of the present disclosure;

FIG. 8 schematically shows a polishing pad manufacturing process according to an exemplary embodiment of the present disclosure;

FIG. 9 schematically shows a system for manufacturing a polishing pad according to an exemplary embodiment of the present disclosure;

FIG. 10 schematically shows an enlarged view of a molding roller unit according to an exemplary embodiment of the present disclosure;

FIGS. 11A and 11B schematically show molding roller units according to exemplary embodiments of the present disclosure;

FIG. 12 schematically shows a system for manufacturing a polishing pad according to an exemplary embodiment of the present disclosure; and

FIG. 13 schematically shows a system for manufacturing a polishing pad according to an exemplary embodiment of the present disclosure.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION

Advantages and features of the present disclosure and a method of achieving the same will become apparent with reference to the accompanying drawings and exemplary embodiments described below in detail. However, the present disclosure is not limited to the exemplary embodiments described herein and may be embodied in variations and modifications. The exemplary embodiments are provided merely to allow one of ordinary skill in the art to understand the scope of the present disclosure, which will be defined by the scope of the claims. Accordingly, in some embodiments, well-known operations of a process, well-known structures, and well-known technologies will not be described in detail to avoid obscure understanding of the present disclosure. Throughout the specification, same reference numerals refer to same elements.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

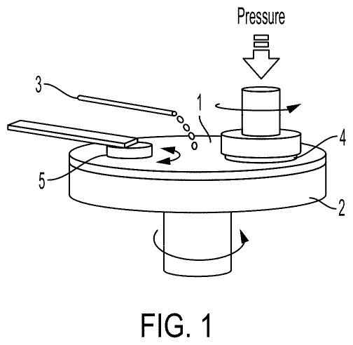

The subject matters of the present disclosure include polishing pads including a plurality of micro polishing structures, systems for manufacturing the same, and methods for manufacturing the same. The polishing pads according to the present disclosure may exhibit improved thermal characteristics and maintain thermal stability during the CMP processes. In addition, the polishing pads according to the present disclosure may minimize a variation of the surface roughness over time, and thus, may provide technical advantages such as increased reliability and repeatability for the polishing process. Consequently, wafer planarization may be more reliably obtained. Moreover, due to the lower operating temperature, the polishing pads according to the present disclosure may last longer and require less frequent replacement, providing economic advantages. Defects of the polishing pad may be minimized as well. A conditioning tool such as the conditional disc 5 in FIG. 1 may be eliminated from the CMP setup, which may simplify the process and the CMP equipment configuration. In addition, since the polishing pads according to the present disclosure may maintain a more stable polishing temperature, the temperature of polishing slurry may be prevented from varying. Less temperature variation of the polishing slurry is advantageous because the temperature variation of the polishing slurry may vary the pH of the polishing slurry, and the pH of the polishing slurry may affect agglomeration of abrasive particles within the polishing slurry. Further, the systems and methods for manufacturing the polishing pads according to the present disclosure may provide high-throughput, improved quality-control, and cost-reduction for manufacturing the polishing pads that include a plurality of micro polishing structures.

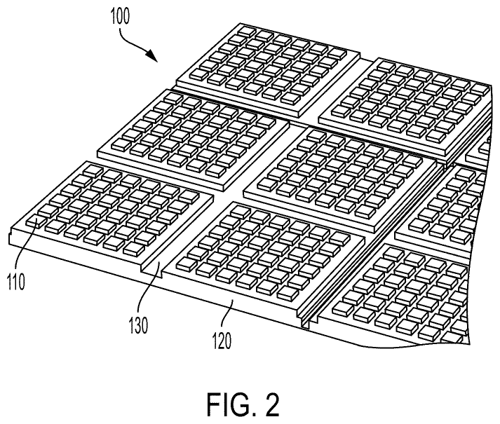

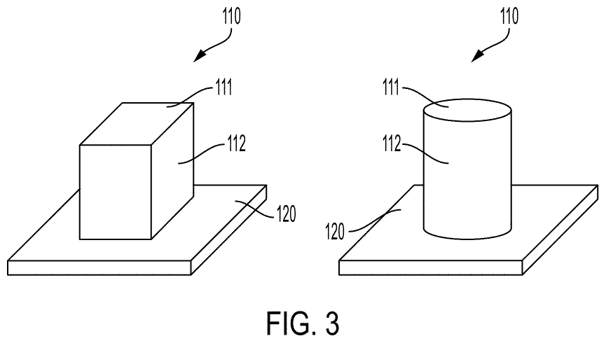

Hereinbelow, the polishing pads according to the present disclosure will be described with reference to FIGS. 2 and 3. FIG. 2 shows a polishing pad according to an exemplary embodiment of the present disclosure, and FIG. 3 depicts an individual polishing structure of the polishing pad according to exemplary embodiments of the present disclosure. As shown in FIGS. 2 and 3, the polishing pad 100 may include a plurality of polishing structures 110 that protrude from a supporting layer 120. Each of the plurality of polishing structures 110 may include an extended surface 111 formed substantially as a horizontal plane and a side surface 112 substantially vertical and perpendicular to the extended surface 111. The polishing structures 110 may be formed in various geometries. For example, the polishing structures 110 may include a polygon such as a triangle, a quadrangle, a pentagon, a hexagon, and the like. The polishing structures 110 may also include a circle, an ellipse, or any free-curved shapes. Further, the polishing structures 110 may include a geometry which is a combination of two or more shapes. In some embodiments, the polishing structures 110 may include a plurality of unit patterns separately disposed from one another. Additionally or alternatively, the polishing structures 110 may include a plurality of unit patterns that are laterally connected with at least some others to form a network of unit patterns.

An area ratio of the extended surface 111 with respect to the polishing pad 100 may be equal to or greater than about 1% and equal to or less than about 80%. For example, the area ratio of the extended surface 111 with respect to the polishing pad 100 may be about 1%, about 5%, about 10%, about 15%, about 20%, about 25%, about 30%, about 35%, about 40%, about 45%, about 50%, about 55%, about 60%, about 65%, about 70%, about 75%, or about 80%. Herein, the area ratio of the extended surface 111 with respect to the polishing pad 100 may refer to a ratio of the total area of the extended surface 111 within the polishing pad 100 with respect to a planform area of the polishing pad 100. Similarly, the area ratio may be calculated as a sum of the area of the extended surface 111 within a unit area of the polishing pad 100.

In case the polishing pad 100 is uneven and the supporting layer 120 is rigid, the polishing pad 100 may exert uneven polishing pressures to the manufacturing article such as a wafer. To prevent the polishing pad 100 from exerting uneven polishing pressures on the manufacturing article, the supporting layer 120 may be formed with a material that is more flexible or pliable than the polishing structures 110. In other words, the polishing structures 110 may include a first material, and the supporting layer 120 may include a second material. The first material and the second material may be same or different. In particular, a first hardness of the first material may be greater than a second hardness of the second material. In other words, the second hardness of the second material may be less than the first hardness of the first material to allow the polishing pad 100 to exert more uniform pressure to the manufacturing article. In some embodiments, the supporting layer 120 may exhibit a hardness that is less than the hardness of the polishing structures 110 while the first material of the polishing structures 110 and the second material of the supporting layer 120 are same, by adding different additives and/or fabricating them with particular structures.

Due to the less rigid and more pliable second material of the supporting layer 120, the pressing force may be more evenly distributed across the polishing pad surface even with a presence of unevenness and/or thickness variations in the polishing pad, and thereby the manufacturing article such as a wafer may be polished more smoothly (e.g., with a higher flatness or a higher evenness). In other words, the softer supporting layer 120 may allow the polishing structures 110 to more compliantly follow the surface topology or geometry of the surface of the manufacturing article when the polishing pad 100 and the manufacturing article are pressed.

The materials for the polishing structures 110 and/or the supporting layer 120 may include polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, p-phenylene sulfide, or the like.

The first hardness of the polishing structures 110 may be between about Shore 30D and about Shore 80D (inclusive) in terms of Shore Hardness scales. By way of example, the first hardness may be about Shore 30D, about 35D, about 40D, about 45D, about 50D, about 55D, about 60D, about 65D, about 70D, about 75D, or about 80D. The second hardness of the supporting layer 120 may be between about Shore 20A and about Shore 100A (inclusive) in terms of Shore Hardness scales. By way of example, the second hardness may be about Shore 20A, about 25A, about 30A, about 35A, about 40A, about 45A, about 50A, about 55A, about 60A, about 65A, about 70A, about 75A, about 80A, about 85A, about 90A, about 95A, or about 100A. The first material may be a composite material that includes one or more additives to increase the hardness and/or wear resistance. Further, the polishing structures 110 may be coated to increase wear resistance. By way of example, one or more of Teflon, boron nitride, or carbon nanotube may be included as the additives and/or used as the coating material. The Teflon coating may prevent or reduce the deformation of the polishing structures 110 due to the heat during the polishing by decreasing its thermal conductivity. Boron nitride may increase the mechanical strength.

In some embodiments, the supporting layer 120 may be divided into a plurality of independent sections by at least one groove 130. The groove 130 may allow the polishing structures 110 to move in a more flexible manner by providing smaller and divided sections. Moreover, the groove 130 may enhance supply and discharge of the polishing slurry, and thereby allow the heat from the polishing structures 110 to dissipate more efficiently.

In operation, the polishing structures 110 may experience abrasion during the CMP process. The abrasion of the polishing structures 110 may lead to variation of the surface contact area of the polishing structures 110 with the manufacturing article. To minimize the variation of the contact area, the polishing structures 110 may be designed to minimize a variation of a horizontal cross-sectional area. Herein, the horizontal cross-section of the polishing structures 110 may be understood as a lateral cross-section that is perpendicular to a length direction or a protruding direction of the polishing structures 110. The lengthwise variation of the horizontal cross-sectional area of the polishing structures 110 may be equal to or less than about 50%. By way of example, the variation of the horizontal cross-sectional area of the polishing structures 110 may be less than about 1%, about 5%, about 10%, or about 20% along the protrusion direction thereof. Due to the minimal variation in the horizontal cross-sectional area of the polishing structures 110, the effective contact area between the polishing pad 100 and the manufacturing article may be maintained substantially constant even when the polishing structures 110 wear out and the length (L) of the polishing structures 110 gradually decreases.

In some embodiments, the thickness of the supporting layer 120 may be in a range of about 0.1 mm to about 5 mm. By way of example, the thickness of the supporting layer 120 may be about 0.1 mm, about 0.2 mm, about 0.3 mm, about 0.4 mm, about 0.5 mm, about 0.6 mm, about 0.7 mm, about 0.8 mm, about 0.9 mm, about 1 mm, about 2 mm, about 3 mm, about 4 mm, or about 5 mm. The protruding length of the polishing structures 110 may be in a range of about 10 μm to about 500 μm. By way of example, the protruding length of the polishing structures 110 may be about 10 μm, about 20 μm, about 30 μm, about 40 μm, about 50 μm, about 100 μm, about 150 μm, about 200 μm, about 250 μm, about 300 μm, about 350 μm, about 400 μm, about 450 μm, or about 500 μm.

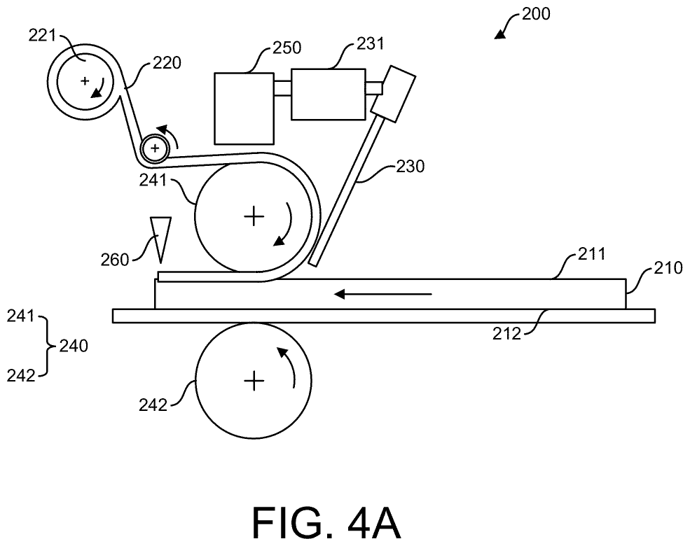

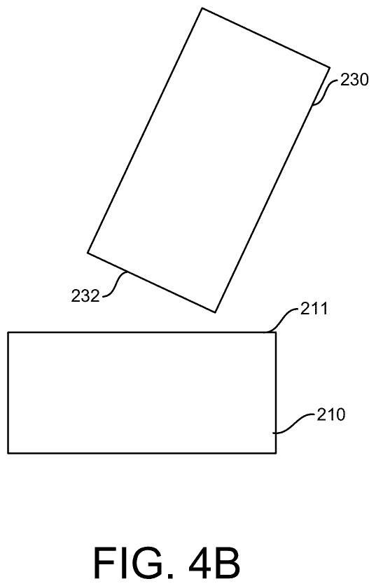

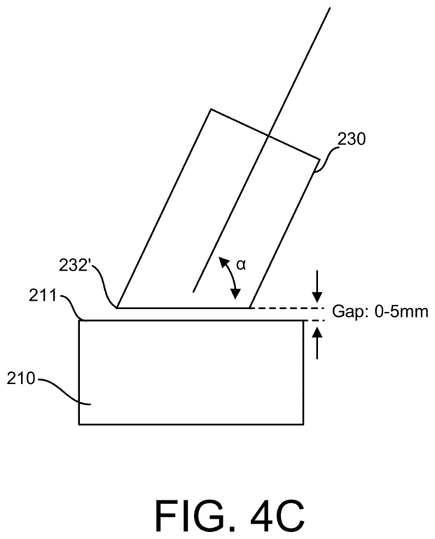

Aspects of the present disclosure provide systems for manufacturing polishing pads having a plurality of polishing structures formed on a supporting layer. Hereinbelow, the systems for manufacture the polishing pads according to the present disclosure will be described with reference to FIGS. 4A-4C, 5, and 6.

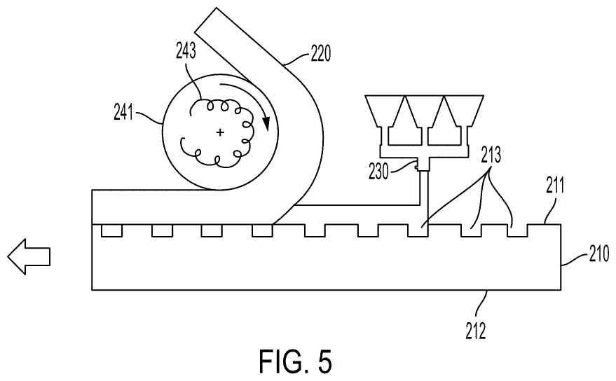

FIGS. 4A-4C and 5 schematically show a system 200 for manufacturing polishing pads according to an exemplary embodiment of the present disclosure. The system 200 for manufacturing polishing pads may include a mold 210, a dispenser 230, and a laminating roller unit 240. The mold 210 may have a top surface 211 and a bottom surface 212, and the top surface 211 of the mold 210 may include a plurality of recesses 213, which correspond to polishing structures 110 of the polishing pads 100 as described above. The system 200 may be provided with a roll of base film, in which the base film 220 is wound around a roll (or a spool) 221. Upon completion of the manufacturing process, the base film 220 may serve as the supporting layer 120 of the polishing pad 100 as described above. The system 200 may further include a dispenser 230, which is configured to dispense a polymer mix onto the mold 210, allowing the polymer mix to fill the plurality of recesses 213 of the mold 210. Thereafter, the base film 220 may be laminated on the top surface 211 of the mold 210. The polymer mix, when cured, may be formed into the shape of the plurality of recesses 213 of the mold, and may be adhered to the base film 220 to form the polishing structures of the polishing pads.

For laminating the base film 220 on the top surface 211 of the mold 210, the system 200 may include a laminating roller unit 240. In some embodiments, the laminating roller unit 240 may include a first roller 241 and a second roller 242, and may laminate the base film 220 on the top surface 211 of the mold 210 by press-rolling them between the first roller 241 and the second roller 242. The laminating roller unit 240 may apply pressure to the base film 220 against the mold 210. In some embodiments, the pressure may be up to about 10 psi. For example, the pressure may be about 1 psi, about 2 psi, about 3 psi, about 4 psi, about 5 psi, about 6 psi, about 7 psi, about 8 psi, about 9 psi, or about 10 psi.

In brief, the base film 220 may be unwound from the roll 221, transferred to the first roller 241 of the laminating roller unit 240, and laminated on the mold 210, in which the polymer mix is filled or coated. The mold 210 may be moved from a first side (e.g., the right-hand side of FIG. 4A) toward a second side (e.g., the left-hand side of FIG. 4A), and during the translation, the polymer mix may be coated and the base film 220 may be laminated beginning from the second side (e.g., left) and advancing toward the first side (e.g., right). In some embodiments, the translation speed (or the “feeding” speed) of the mold 210 may be selected from about 0.1 feet/min to about 10 feet/min, depending on the curing time for the polymer mix. For example, the translation speed of the mold 210 may be set to about 0.2 feet/min, about 0.3 feet/min, about 0.4 feet/min, about 0.5 feet/min, about 0.6 feet/min, about 0.7 feet/min, about 0.8 feet/min, about 0.9 feet/min, about 1 feet/min, about 2 feet/min, about 3 feet/min, about 4 feet/min, about 5 feet/min, about 6 feet/min, about 7 feet/min, about 8 feet/min, about 9 feet/min, or about 10 feet/min. In some embodiments, the translation speed may be implemented to be variable and/or feedback-controlled based on the temperatures of the mold 210 and/or the laminating roller unit 240 or other manufacturing conditions.

When a full length of the mold 210 is laminated with the base film 220, the base film 220 may be cut along a transverse direction of the mold 210, which is perpendicular to the feeding direction of the mold 210 and parallel with the rotating axis of the laminating roller unit 240. For cutting the base film 220, the system 200 may further include a cutter 260. The cutter 260 may be implemented as a shearer that shears the base film 220 along its entire width at once or as a blade that linearly moves along a direction parallel with the rotating axis of the laminating roller unit 240.

FIGS. 4B and 4C show examples of a nozzle tip 232 of the dispenser 230 of the system 200 shown in FIG. 4A. As shown in FIG. 4B, the nozzle tip 232 of the dispenser 230 may be formed with a squarely cut tip. On the other hand, as shown in FIG. 4C, the nozzle tip 232′ of the dispenser 230 may be formed with a predetermined angle with respect to the axis of the dispenser 230. Due to the angled configuration, since the entire dispensing portion of the nozzle tip 232′ may be disposed more evenly and closely to the top surface 211 of the mold 210, the angled nozzle tip 232′ may squeeze the dispensed polymer mix onto the mold 210 while it supplies the polymer mix. By way of example, the angled nozzle tip may be spaced apart from the top surface 211 of the mold 210 with a gap of about 0 to about 5 mm. For example, the gap between the nozzle tip 232′ of the dispenser 230 and the top surface 211 of the mold 210 may be about 0.5 mm, about 1.0 mm, about 1.5 mm, about 2.0 mm, about 2.5 mm, about 3.0 mm, about 3.5 mm, about 4.0 mm, about 4.5 mm, or about 5.0 mm.

A slant angle α of the nozzle tip 232′ with respect to the axis of the dispenser 230 may be configured to be substantially same as a tilting angle of the dispenser 230 with respect to the mold 210. By way of example, the slant angle α may be between about 45° to about 60°. For example, the slant angle α may be about 45°, about 50°, about 55°, or about 60°.

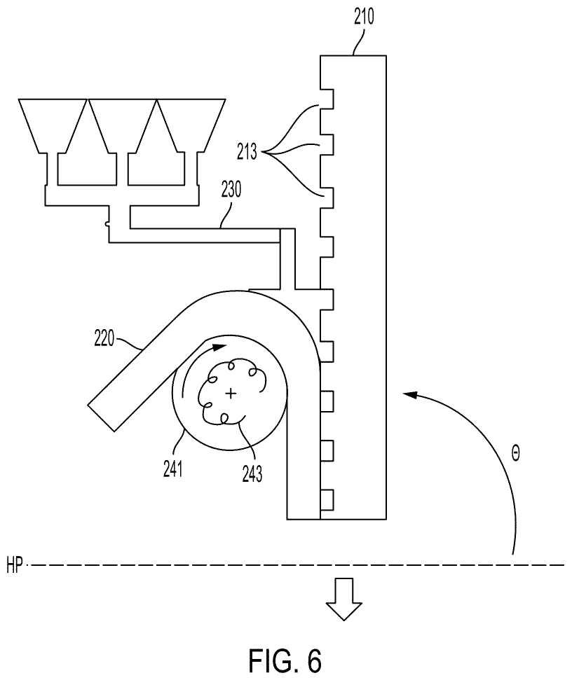

FIG. 6 shows a variation of the system 200 according to an embodiment of the present disclosure. In this example, the mold 210 may be translated (or “fed”) in a substantially vertical direction or downward. More generally, the mold 210 may be press-rolled through the laminating roller unit 240 while the mold 210 is inclined with respect to a horizontal plane HP by a predetermined tilting angle θ. In some embodiments, the tilting angle θ may be between about 10° and about 90°. For example, the tilting angle θ may be set to about 10°, about 15°, about 20°, about 25°, about 30°, about 35°, about 40°, about 45°, about 50°, about 55°, about 60°, about 65°, about 70°, about 75°, about 80°, about 85°, or about 90°.

When the tilting angle θ is present and is greater than about 10°, the dispensed polymer mix may be distributed or dispersed more readily and evenly across the lateral direction (i.e. the direction parallel with the rotational axis of the laminating roller unit 240) due to the gravity. With such a configuration, the polymer mix may be prevented from being merely pushed away by the laminating roller unit 240 toward the first end of the mold 210 without filling the plurality of recesses 213. Accordingly, the situation where the polymer mix is inadvertently cured without filling the plurality of recesses 213 of the mold 210 may be avoided.

Further, in some embodiments, the system 200 may include a plasma treater 250 to treat the base film 220 prior to being laminated on the mold 210. By plasma-treating a surface of the base film 220 that is to be laminated to the mold 210, as shown in FIG. 4A, impurities may be removed from the surface of the base film 220, and the surface energy may be increased, which may enhance adhesion of the polymer mix (and the polishing structures resulting therefrom) to the base film 220.

In the embodiment shown in FIGS. 4A-4C, 5, and 6, the dispenser 230 may dispense the polymer mix between the mold 210 and the base film 220 prior to laminating them. In some embodiments, to enhance the uniformity of the polymer mix being disposed on the mold 210, the dispenser 230 may dispense the polymer mix while moving linearly along the transverse direction of the mold 210. In such embodiments, the system 200 may further include a linear motor guide 231 to move the dispenser 230 along the transverse direction.

The polymer mix may be cured and adhered to the base film 220 to form the plurality of polishing structures thereon. The curing may be performed in two or more steps, e.g., a first (e.g., primary) curing and a second (e.g., secondary or final) curing. During the first curing step, the polymer mix may be cured enough to maintain the shape of the polishing structures even if demolded from the mold 210. At this state, the polymer mix may be still unable to bear a full mechanical load. The polymer mix may be completely cured by a second or subsequent curing steps to be able to bear a full mechanical load and to function as the polishing structures of the polishing pads.

In some embodiments, the first curing step may be performed while the mold 210 is being press-rolled by the laminating roller unit 240. In such embodiment, in order to perform the first curing step, the laminating roller unit 240 may include a heater 243 therein to provide heat to the surface of the first roller 241, the second roller 242, or both at a predetermined temperature. For example, the predetermined temperature may be between about 20° C. and about 120° C., depending on the polymer material used in the polymer mix. Here, although FIGS. 5 and 6 depict a configuration where the heater 243 is embedded within the laminating roller unit 240, the present disclosure is not limited thereto. The heater 243 may be disposed anywhere in the vicinity of the laminating roller unit 240 to effectively perform the first curing step.

Alternatively or additionally, the first curing may be performed or continued to be performed after the mold 210 is ejected from the laminating roller unit 240 and the base film 220 is cut by the cutter 260. In such embodiments, the mold 210 may be ejected from the laminating roller unit 240 as a batch where the base film 220 is disposed on the top surface 211 thereof, and the polymer mix is disposed between the mold 210 and the base film 220. This batch of the ejected mold 210 may be transported to and cured within a temperature-controlled chamber. The temperature-controlled chamber may be maintained at a temperature between about 20° C. and about 120° C. and/or may be filled with air or an inert gas, e.g., nitrogen or argon. During the curing in the temperature-controlled chamber, pressure may be applied on the base film 220 against the mold 210. By way of example, the pressure may be applied by disposing a weight on top of the base film 220. The curing time may be between about 10 minutes and about 24 hours. By way of example, the curing time may be about 10 minutes, about 20 minutes, about 30 minutes, about 1 hour, about 2 hours, about 3 hours, about 4 hours, about 5 hours, about 6 hours, about 7 hours, about 8 hours, about 9 hours, about 10 hours, about 11 hours, about 12 hours, about 13 hours, about 14 hours, about 15 hours, about 16 hours, about 17 hours, about 18 hours, about 19 hours, about 20 hours, about 21 hours, about 22 hours, about 23 hours, or about 24 hours.

After the first curing step, the base film 220 and the polishing structure, formed from the polymer mix, may be demolded from the mold 210 such that a bulk sheet of the polishing pad is obtained. To facilitate the demolding process, in some embodiments, the mold 210 may be applied with a demolding agent prior to being fed into the system 200.

The demolded bulk sheet of the polishing pad may be subject to a second curing step. In some embodiments, the second curing step may be performed at a temperature between about 20° C. and about 120° C. in an air or inert gas environment. The second curing step may be performed for about 1 hour to about 24 hours. In some embodiments, humidity may be controlled during the first curing step, the second curing step, or both. For example, the humidity of the curing chamber may be controlled to be equal to or below about 50%. By way of example, the humidity may be controlled at about 40% or below, or about 30% or below. Without being bound by any theories, lower humidity generally provides more desirable conditions for the curing.

Once the bulk sheet of polishing pad is fully cured, it may be sheared (e.g., press-cut) to make a plurality of polishing pads therefrom. In some embodiments, a plurality of bulk sheets of polishing pad may be manufactured and stacked together, and then may be cut into a plurality of polishing pads. In some embodiments, before or after the shearing step, an adhesive may be laminated on the back surface of the polishing pads. For example, the adhesive may be a double-sided tape.

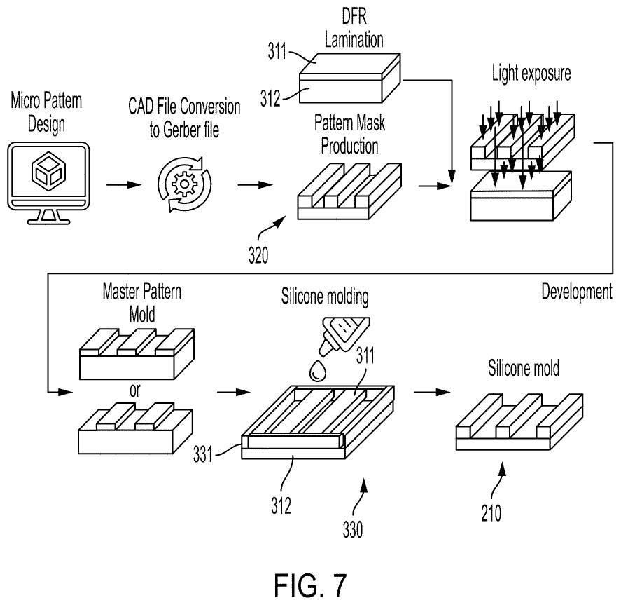

Herein, prior to the manufacturing process of the polishing pads, the mold 210 may be fabricated using a master mold. FIG. 7 describes an example of manufacturing process of the mold 210. Referring to FIG. 7, a dry film resist (DFR) 311 may be laminated or deposited on a substrate 312. In the meantime, a photomask 320 may be prepared using techniques known in the art. For example, the micro patterns for the polishing structures may be designed using a computer aided design (CAD) tool, the CAD file may be converted to a Gerber file, and the photomask 320 may be created (e.g., printed) using the Gerber file.

The pattern of the photomask 320 may be transferred onto the DFR 311 that is deposited on the substrate 312 via photolithography, in which the DFR 311 is exposed with light having suitable wavelengths through the photomask 320. Depending on whether the DFR 311 is a photo-positive resist or a photo-negative resist, the exposed portion of the DFR 311 may be removed or may remain during the development. After the development, a master mold 330 may be created, optionally by adding a mold frame 331 onto the substrate 312.

Subsequently, silicone or other mold materials may be poured into the master mold 330, cured, and demolded to create the mold 210. The mold material may include silicone, or a metal such as nickel. However, the mold material is not limited thereto, and various other materials may be used to fabricate the mold 210 for manufacturing the polishing structures of the polishing pads.

In some embodiment, instead of using photolithography as described above, other machining techniques, such as electrical discharge machining (EDM), 3-D printing, or laser machining, which are capable of creating the micro patterns with acceptable tolerances, may be used.

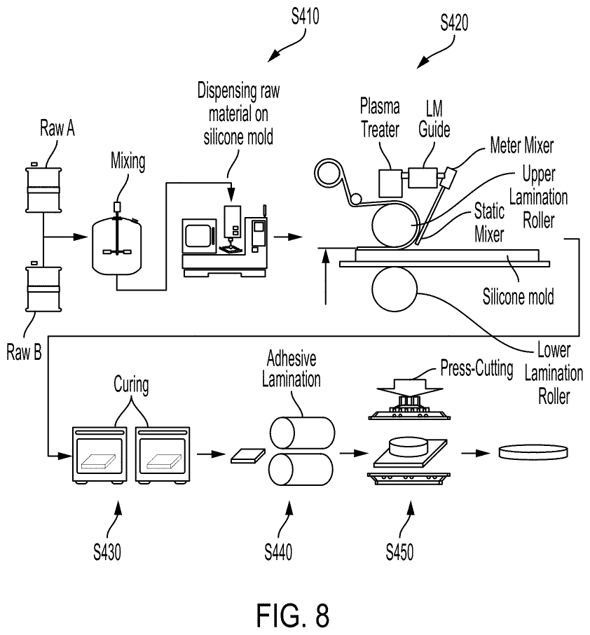

Aspects of the present disclosure also include methods for manufacturing polishing pads including a plurality of polishing structures formed on a surface thereof. Hereinbelow, a process of manufacturing the polishing pads according to an exemplary embodiment of the present disclosure will be described with reference to FIG. 8. Referring to FIG. 8, a mold may be fabricated (S410) using a process as described above (e.g., using a master mold that is fabricated via photolithography). Subsequently, a bulk sheet of polishing pad may be manufactured (S420). More particularly, the process of manufacturing the bulk sheet of polishing pad (S420) may include providing the mold that includes a plurality of recesses formed on the top surface thereof, dispensing a polymer mix on the mold and allowing the polymer mix to fill the plurality of recesses, laminating a base film on the top surface of the mold, curing the polymer mix; and demolding the base film and the cured polymer mix.

Further, the bulk sheet of polishing pad may be cured for the second time (S430) in a curing chamber, and then an adhesive may be applied to the back surface of the sheet (S440). Finally, the polishing pad bulk sheet may be cut (e.g., press-cut) into a plurality of polishing pads (S450). In some embodiments, a plurality of bulk sheets may be stacked together and then be cut into the polishing pads.

In some embodiments, subsequent to the laminating or the curing, the manufacturing process may include cutting the base film along a transverse direction of the mold. Further, the laminating may be performed with the laminating roller unit 240 of the system 200 as described above, and the laminating roller unit may move the mold at a speed between about 0.1 feet/min and about 10 feet/min while pressing the base film and the mold at a pressure between 0 and about 10 psi. In some embodiments, the curing may occur while the polymer mix is press-rolled by the laminating roller unit. In such embodiments, the surface of the laminating roller unit may be heated to a temperature between about 20° C. and about 120° C.

Prior to the laminating, a surface of the base film to be laminated to the mold may be plasma-treated to remove impurities on the surface and/or to increase the surface energy thereof.

In some embodiments, during the laminating, the mold may be press-rolled through the laminating roller unit while the mold is inclined with respect to a horizontal plane by a predetermined tilting angle θ. For example, the predetermined tilting angle may be between about 10° and about 90°.

Herein, the base film may be primarily formed with one or more materials including polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, p-phenylene sulfide, or any combination thereof.

The polymer mix may include one or more pre-polymer and one or more curing agents. In some embodiments, the polymer mix may further include one or more additives. In some embodiments, the pre-polymer may include one or more of polyurethane, polybutadiene, polycarbonate, polyoxymethylene, polyamide, epoxy, acrylonitrile butadiene styrene copolymer, polyacrylate, polyetherimide, acrylate, polyalkylene, polyethylene, polyester, natural rubber, polypropylene, polyisoprene, polyalkylene oxide, polyethylene oxide, polystyrene, phenolic resin, amine, urethane, silicone, acrylate, fluorene, phenylene, pyrene, azulene, naphthalene, acetylene, p-phenylene vinylene, pyrrole, carbazole, indole, azepine, aniline, thiophene, 3,4-ethylenedioxysiphen, p-phenylene sulfide, or any combination thereof.

The additives may enhance the hardness and/or wear-resistance of the polishing structures. In some embodiments, Teflon, graphene, carbon nanoparticles, or any combination thereof may be added as the additives.

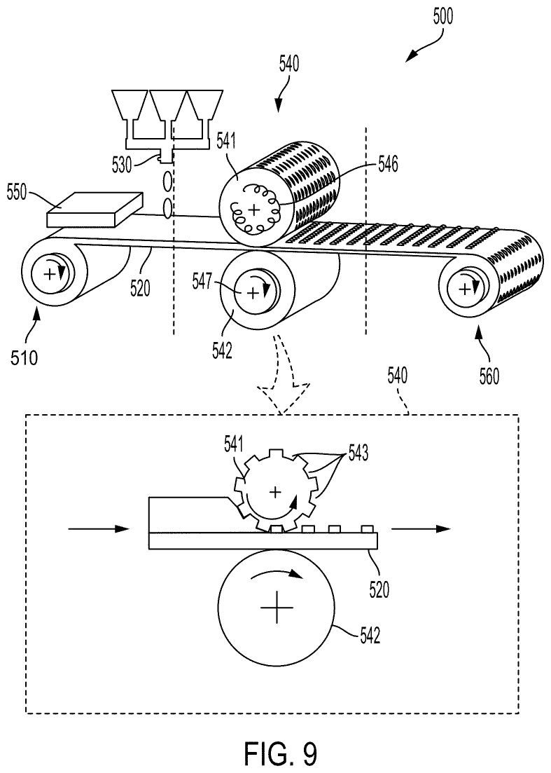

Hereinbelow, a system and a method for manufacturing the polishing pads according to another exemplary embodiment of the present disclosure will be described with reference to FIGS. 9, 10, 11A and 11B. In this embodiment, the bulk sheet of polishing pads may by manufactured continuously, compared to a batch or semi-batch process of the embodiments shown in FIGS. 4A-8.

Referring to FIG. 9, a system 500 for manufacturing polishing pads may include a molding roller unit 540, on which a plurality of recesses 543 that correspond to the polishing structures of the polishing pads are formed. In this embodiment, the molding roller unit 540 may perform the functions of both the mold 210 and the laminating roller unit 240 of the system 200 described above. The system 500 may also include a first roll 510, on which a base film 520 is wound, and a second roll 560, on which the base film 520 formed with the polishing structures is wound. The system 500 may further include a dispenser 530 that dispenses a polymer mix on a surface of the base film 520, and a plasma-treater 550 that provides a plasma-treatment of the surface of the base film 520 to remove impurities and/or to increase the surface energy thereof.

During the manufacturing process, the polymer mix may be dispensed from the dispenser 530 and be coated on the base film 520, and the molding roller unit 540 may imprint the polishing structures on the polymer mix. In order for the molding roller unit 540 to be able to imprint the polishing structures on the polymer mix, the molding roller unit 540 may include a first roller 541 and a second roller 542 as shown in FIG. 9. In such embodiments, the first roller 541 may include the plurality of recesses 543, which correspond to the polishing structures of the polishing pads. Further, the first roller 541, the second roller 542, or both may include a heater 546 to heat the surface thereof to a predetermined temperature. For example, the predetermined temperature may be between about 20° C. and about 120° C. In some embodiments, the second roller 542 may include a cooler 547 to control the temperature of the back side of the base film 520. In some other embodiments, the cooler 547 may be provided separately from the second roller 542.

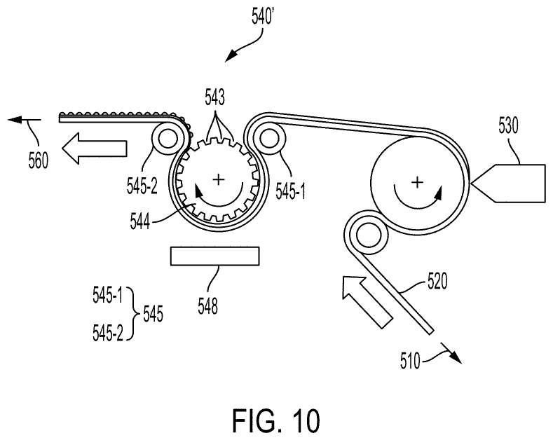

As shown in FIG. 10, in some embodiments, the molding roller unit 540′ may include a molding roller 544 that includes the plurality of recesses 543, and a tensioning unit 545 that presses the base film 520 onto the molding roller 544. Further, the tensioning unit 545 may include an upstream roller 545-1 and a downstream roller 545-2. The upstream roller 545-1 may be disposed between the molding roller 544 and the first roll 510, and the downstream roller 545-2 may be disposed between the molding roller 544 and the second roll 560. In particular, the upstream roller 545-1 and the downstream roller 545-2 may be disposed to contact a back surface of the base film 520 where no polymer mix is coated, and the molding roller 544 may contact the surface of the base film 520 where the polymer mix is coated. In order to apply a tension and to press the base film 520 against the molding roller 544, the speeds of the upstream roller 545-1 and the downstream roller 545-2 may be controlled. For example, the downstream roller 545-2 may be rotated faster than the upstream roller 545-1 such that a tension is created. In some embodiments, in order to apply a tension and to press the base film 520 against the molding roller 544, the upstream roller 545-1 may be configured to have a higher resistance than the downstream roller 545-2.

The plurality of recesses 543 may be formed on the first roller 541 and the molding roller 544 using various techniques. For example, the first roller 541 or the molding roller 544 may be casted using a master mold. Alternatively, a sheet mold that includes the plurality of recesses 543 may be wrapped around a cylinder to make the first roller 541 or the molding roller 544. In such embodiments, the sheet mold may be fabricated using similar processes for manufacturing the mold 210 of the system 200, as described above. In some embodiments, the plurality of recesses 543 may be formed on the first roller 541 or the molding roller 544 by laser engraving. For laser engraving, the first roller 541 or the molding roller 544 may be formed with silicone. The silicone surface may be illuminated with laser such that the exposed portion is melt/burnt and removed. Consequently, the plurality of recesses 543 may be formed on the silicone surface, which act as a mold for the polishing structures formed on the polishing pads.

Referring to FIG. 10 again, the molding roller unit 540′ may further include a curing unit 548 that applies light (e.g., UV light) and/or heat to the molding roller 544 such that the polymer mix is cured while being imprinted with the molding roller 544. This first curing step may be more important for this continuous implantation of the manufacturing process because the polymer mix is released from the molding roller unit 540′ before the molding roller unit 540′ rotates one full turn. The polymer mix is required to be cured enough to maintain the shape of the polishing structures when the base film is released from the molding roller unit 540′.

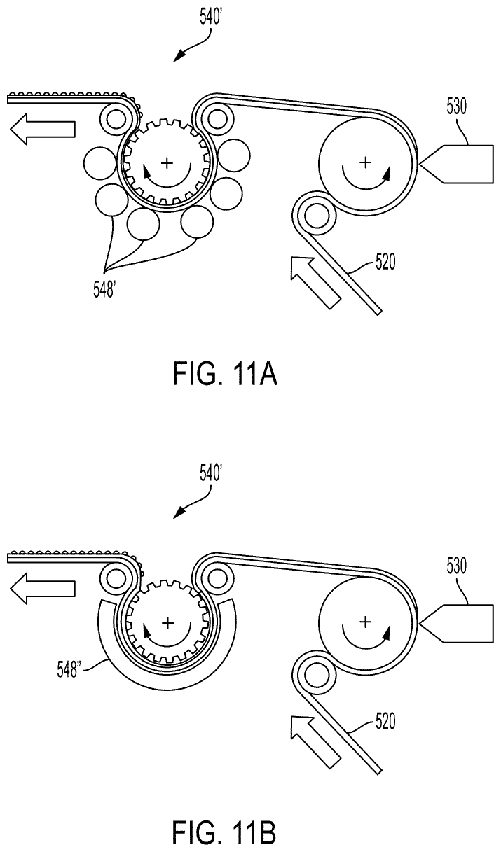

As shown in FIG. 11A, one or more heated rollers 548′ may be implemented as the curing unit. In such embodiments, the one or more heated rollers 548′ may be disposed in proximity to or in contact with the molding roller 544 with the base film 520 therebetween. In other embodiments, the curing unit may be implemented as a heated sleeve 548″ that is disposed in proximity to the molding roller 544 with the base film 520 therebetween, as shown in FIG. 11B. The surface of the heated rollers 548′ and the heated sleeve 548″ may be heated to a predetermined temperature, e.g., between about 20° C. and about 120° C.

Hereinbelow, a process of manufacturing the polishing pads according to another embodiment of the present disclosure will be described. In this embodiment, the polishing pad manufacturing process may be performed using the system 500, which is described above.

The process of manufacturing the polishing pads may include unwinding a base film from a first roll, dispensing or coating a polymer mix on a surface of the base film, and rolling the base film and the coated polymer mix through a molding roller unit to imprint polishing structures on the polymer mix. As described above, the molding roller unit may include a plurality of recesses that correspond to the polishing structures. Subsequently, the base film formed with the polishing structures may be wound onto a second roll.

In some embodiments, the molding roller unit may be heated to a predetermined temperature to achieve a first curing step. For example, the predetermined temperature may be between about 20° C. and about 120° C.

For a second curing step, the second roll may be placed in a curing chamber, which is maintained at a temperature between about 20° C. and about 120° C. in an air or inert gas environment. Finally, after the second curing step, the wound bulk sheet of the polishing pads may be sheared or press-cut into the polishing pads. Further, before or after the cutting, an adhesive may be applied on the back side of the polishing pads. For example, a double-sided tape may be applied on the back side of the polishing pads before or after cutting the bulk sheet of the second roll.

Although not described in detail, the systems 200 and 500 for manufacturing the polishing pads may include additional roller units as well as the roller units shown in FIGS. 4A-4C, 5, 6, 8-10, 11A, and 11B to adjust the advancing direction of the base film at various locations as necessary.

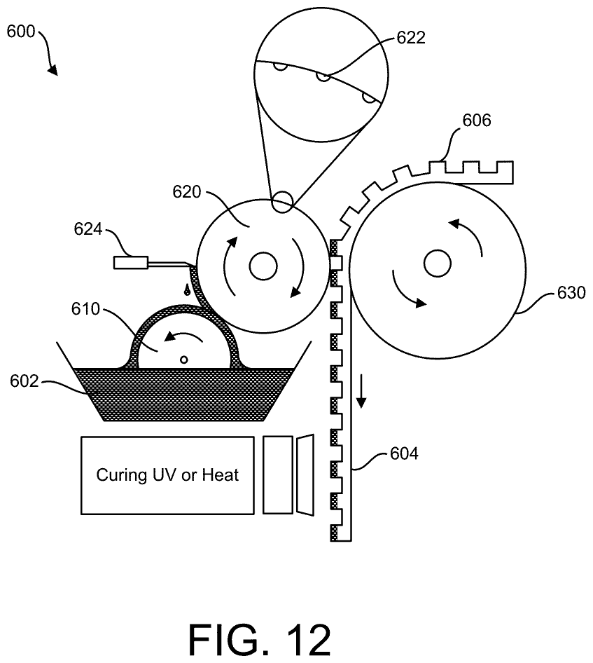

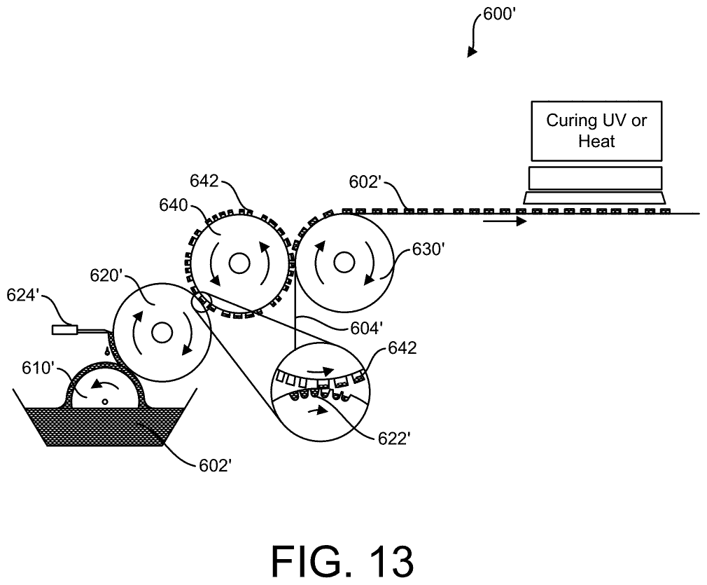

Hereinbelow, a system and a method for manufacturing the polishing pads according to yet another exemplary embodiment of the present disclosure will be described with reference to FIGS. 12 and 13.

Referring to FIG. 12, a system 600 for manufacturing polishing pads may include a first roller 610, at least a portion of which is immersed in a reservoir of polymer mix 602. By way of example, the first roller 610 may be made of a felt material to retain the polymer mix 602 more effectively. Subsequently, the polymer mix 602 may be transferred from the first roller 610 to a second roller 620. The second roller 620 may include a plurality of cells 622 on a peripheral surface thereof. Each of the plurality of cells 622 may retain a controlled amount of polymer mix 602 therein. To control the amount of the polymer mix 602 in each of the plurality of cells 622 of the second roller 620, a blade 624 may be provided adjacent to the second roller 620 and may scrape off excess amount of the polymer mix 602 from the second roller 620. Further, a third roller 630 may transport a base film 604 between the second roller 620 and the third roller 630 such that the polymer mix 602 retained in the plurality of cells 622 of the second roller 620 may be transferred onto a surface of the base film 604.

In some embodiments, the base film 604 may include a plurality of microscale features 606 on the surface thereof, which correspond to the polishing structures of the polishing pads, and the polymer mix 602 may be printed on a top surface of the microscale features 606. In some other embodiments, the surface of the base film 604 may be substantially planar, and the polymer mix 602 may be printed on the planar surface of the base film 604, resulting in the plurality of polishing structures formed thereon.

Thereafter, the base film 604 printed with the polymer mix 602 may undergo a first curing step using UV light and/or heat. Alternatively or additionally, the printed base film 604 may be rolled on a product transfer roller, in a manner similar to the exemplary embodiment shown in FIG. 9, for further processing such as a second curing step.

In some embodiments, as shown in FIG. 13, a system 600′ for manufacturing polishing pads may include a first roller 610′, at least a portion of which is immersed in a reservoir of polymer mix 602′. The polymer mix 602′ may then be transferred to a second roller 620′ from the first roller 610′. The surface of the second roller 620′ may include a plurality of cells 622′ that contain the polymer mix 602′ therein. To scrape off excess amount of the polymer mix 602′ from the second roller 620′, a blade 624′ may be provided adjacent to the second roller 620′. In turn, the second roller 620′ may transfer the polymer mix 602′ to a fourth roller 640 and subsequently onto a base film 604′.

To facilitate more precise transfer of the polymer mix 602′, a plurality of microscale features 642 may be formed on a peripheral surface of the fourth roller 640. The plurality of microscale features 642 formed on the fourth roller 640 may correspond to the plurality of polishing structures to be formed on the polishing pads. By way of example, the plurality of microscale features 642 of the fourth roller 640 may be formed with an elastomeric material such as rubber or silicone. In some embodiments, the fourth roller 640 may include a structure in which an elastomeric sheet having the plurality of microscale features 642 formed thereon is wrapped around a rigid core cylinder.

Herein, although description has been given for a configuration where the second roller 620′ includes the plurality of cells 622′ and the fourth roller 640 includes the plurality of microscale features 642, the present disclosure is not limited to such a configuration. The cells and the microscale features may be formed vice versa, or any of the second roller 620′ or the fourth roller 640′ may have a smooth surface without any recess or protrusion, provided that such smooth surface can transfer the polymer mix 602′ from one roller to another or to the base film 604′ with desired patterns.

The polymer mix 602′ that is transferred from the plurality of cells 622′ of the second roller 620′ to the plurality of microscale features 642 of the fourth roller 640 may then be transferred to the base film 604′. Therefor, a third roller 630′ may be provided in contact with the fourth roller 640 to press-roll the base film 604′ between the fourth roller 640 and the third roller 630′. Consequently, the polymer mix 602′ residing on the surfaces of the plurality of microscale features 642 of the fourth roller 640 may be printed on the base film 604′. Thereafter, the base film 604′ printed with the polymer mix 602′ may undergo a first curing step using UV light and/or heat. In some embodiments, the printed base film 604′ may be rolled on a product transfer roller, in a manner similar to the exemplary embodiment shown in FIG. 9, for further processing such as a second curing step as described above.

Hereinbelow, a process of manufacturing the polishing pads according to the yet another exemplary embodiment of the present disclosure will be described. In this embodiment, the polishing pad manufacturing process may be performed using the system 600 or 600′, which is described above.

The process of manufacturing the polishing pads may include transferring the polymer mix 602 from a reservoir to the first roller 610. Subsequently, the polymer mix 602 may be transferred from the first roller 610 to the second roller 620 based on the viscosity of the polymer mix 602. The second roller 620 may include a plurality of cells 622 on the peripheral surface thereof to retain a controlled amount of polymer mix 602 therein. In some embodiments, excess amount of the polymer mix 602 may be scraped off from the second roller 620 by the blade 624 that is provided adjacent to the second roller 620. The polymer mix 602 may then be printed on the base film 604. To transport the base film 604 and press-roll the base film 604 against the second roller 620, the third roller 630 may be provided in contact with the second roller 620. The polymer mix 602 printed onto the base film 604 may then be subject to a first curing step using UV light and/or heat. During the first curing step, the polymer mix 602 may be cured enough to maintain the shape of the polishing structures.

In some embodiments, the base film 604 printed with the polymer mix 602 may be wound on a product transfer roller for further processing such as a second curing step. The second curing step may be performed at a temperature between about 20° C. and about 120° C. in an air or inert gas environment. The second curing step may be performed for about 1 hour to about 24 hours. In some embodiments, humidity may be controlled during the first curing step, the second curing step, or both. For example, the humidity may be controlled to be equal to or below about 50%. By way of example, the humidity may be controlled at about 40% or below, or about 30% or below. Without being bound by any theories, lower humidity generally provides more desirable conditions for the curing.

In some embodiments, the manufacturing process may further include transferring the polymer mix 602 onto the fourth roller 640 from the second roller 620, and then transferring from the fourth roller 640 onto the base film 604. In such embodiments, the fourth roller 640 may include a plurality of microscale features 642 on the peripheral surface thereof, which correspond to the plurality of polishing structures to be formed on the polishing pads.

As set forth herein, the subject matters of the present disclosure provide polishing pads including a plurality of micro polishing structures, systems for manufacturing the polishing pads, and methods for manufacturing the polishing pads. The polishing pads according to the present disclosure may provide improved thermal stability during the CMP processes, and may maintain more consistent surface roughness of the polishing surface during the CMP processes and throughout the life-span of the polishing pads. Further, the systems and methods for manufacturing the polishing pads according to the present disclosure may provide high-throughput, improved quality-control, and economical manufacturing of the polishing pads that include a plurality of micro polishing structures.

Hereinabove, although the present disclosure is described by specific matters such as concrete components, and the like, the exemplary embodiments and the drawings are provided merely for assisting in the entire understanding of the present disclosure. Therefore, the present disclosure is not limited to the exemplary embodiments described herein. Various modifications and changes can be made by a person of ordinary skill in the art to which the present disclosure pertains. The spirit of the present disclosure should not be limited to the above-described exemplary embodiments, and the following claims as well as all technical spirits modified equally or equivalently to the claims should be interpreted to fall within the scope and spirit of the disclosure.

What is claimed is:

1. A method for fabricating a polishing pad including a plurality of polishing structures, the method comprising:
providing a mold having a top surface and a bottom surface, wherein a plurality of recesses that correspond to the polishing structures are formed on the top surface of the mold;
dispensing a polymer mix on the mold and allowing the polymer mix to fill the plurality of recesses to be formed as the polishing structures;
laminating a base film on the top surface of the mold;
curing the polymer mix to allow the polymer mix to adhere to the base film and to form the polishing structures on the base film; and
demolding the base film and the polishing structures from the mold to obtain a polishing pad sheet.

2. The method of claim 1, wherein the base film is supplied from a roll by being unwound therefrom, and
wherein, subsequent to the laminating or the curing, the base film is cut along a direction parallel to a rotational axis of the roll of the base film.

3. The method of claim 1, wherein the laminating is performed with a laminating roller unit.

4. The method of claim 3, wherein the laminating roller unit comprises a first roller and a second roller, and
wherein the mold, the polymer mix, and the base film are press-rolled between the first roller and the second roller.

5. The method of claim 3, wherein the laminating and the curing are performed with the laminating roller unit, and
wherein the laminating roller unit is heated to a predetermined temperature.

6. The method of claim 1, comprising:
prior to the laminating, plasma-treating a surface of the base film that is to be laminated to the mold to remove impurities on the surface and/or to increase a surface energy.

7. The method of claim 1, wherein the curing further comprises:
pressing the base film against the mold in a temperature-controlled chamber.

8. The method of claim 3, wherein the polymer mix is dispensed on the mold by a dispenser that moves linearly along a direction parallel to a rotational axis of the laminating roller unit.

9. The method of claim 3, wherein, during the laminating, the mold is press-rolled through the laminating roller unit while the mold is inclined with respect to a horizontal plane by a predetermined tilting angle, and
wherein the predetermined tilting angle is between about 10° and about 90°.

10. The method of claim 1, comprising:
subsequent to the demolding, further curing at a temperature between about 20° C. and about 120° C. in an air or inert gas environment.

11. A method for fabricating a polishing pad including a plurality of polishing structures, the method comprising:
unwinding a base film from a first roll;
dispensing a polymer mix on a surface of the base film;
rolling the base film and the polymer mix through a molding roller unit to imprint polishing structures on the polymer mix, wherein the molding roller unit includes a plurality of recesses that correspond to the polishing structures; and
winding the base film formed with the polishing structures onto a second roll.

12. The method of claim 11, wherein the molding roller unit includes a first roller and a second roller, and one of the first roller or the second roller includes the plurality of recesses that correspond to the polishing structures, and
wherein the base film and the polymer mix are press-rolled between the first roller and the second roller.

13. The method of claim 11, wherein the molding roller unit comprises:
a molding roller including the plurality of recesses that correspond to the polishing structures; and
a tensioning unit configured to press the base film onto the molding roller.

14. The method of claim 13, wherein the tensioning unit comprises:
an upstream roller disposed between the molding roller and the first roll; and
a downstream roller disposed between the molding roller and the second roll,
wherein the upstream roller and the downstream roller are disposed to contact a back surface of the base film where no polymer mix is coated, and the molding roller contacts the surface of the base film where the polymer mix is coated, and
wherein speeds of the upstream roller and the downstream roller are controlled to cause the base film to be pressed against the molding roller by a tension created due to a speed difference between the upstream roller and the downstream roller.

15. The method of claim 11, wherein the molding roller unit is heated to a predetermined temperature.

16. The method of claim 11, further comprising:
curing the base film formed with the polishing structures that is wound on the second roll at a temperature between about 20° C. and about 120° C. in an air or inert gas environment.

17. A system for fabricating a polishing pad including a plurality of polishing structures, the system comprising:
a first roll from which a base film is unwound;
a dispenser that dispenses a polymer mix on a surface of the base film being unwound from the first roll;
a molding roller unit that press-rolls the base film and the polymer mix therebetween to imprint polishing structures on the polymer mix; and
a second roll onto which the base film formed with the polishing structures is wound,
wherein the molding roller unit includes a plurality of recesses that correspond to the polishing structures.

18. The system of claim 17, wherein the molding roller unit includes a first roller and a second roller, and one of the first roller or the second roller includes the plurality of recesses that correspond to the polishing structures, and
wherein the base film and the polymer mix are press-rolled between the first roller and the second roller.

19. The system of claim 17, wherein the molding roller unit comprises:
a molding roller including the plurality of recesses that correspond to the polishing structures; and
a tensioning unit configured to press the base film onto the molding roller.

20. A method for fabricating a polishing pad including a plurality of polishing structures, the method comprising:
transferring a polymer mix from a reservoir to a first roller;
transferring the polymer mix from the first roller to a second roller; and
transferring the polymer mix from the second roller onto a base film,
wherein the polymer mix is printed on the base film, thereby forming the plurality of polishing structures.

21. The method of claim 20, wherein the base film is pressed against the second roller via a third roller.

22. The method of claim 20, wherein the second roller includes a plurality of cells on a peripheral surface thereof to retain a controlled amount of the polymer mix therein.

23. The method of claim 20, wherein the base film includes a plurality of microscale features that forms the plurality of polishing structures when coated with the polymer mix.

24. The method of claim 20, further comprising:
transferring the polymer mix from the second roller onto a fourth roller; and
transferring the polymer mix from the fourth roller onto the base film,
wherein the fourth roller includes a plurality of microscale features, which correspond to the plurality of polishing structures to be formed on the polishing pad.

25. A system for fabricating a polishing pad including a plurality of polishing structures, the system comprising:
a first roller, a portion of which is immersed in a reservoir of a polymer mix to transfer the polymer mix from the reservoir;
a second roller disposed in contact with the first roller to transfer the polymer mix from the first roller; and
a third roller that rolls a base film such that the polymer mix is transferred onto the base film,
wherein the polymer mix that is transferred on to the base film forms the plurality of polishing structures.

26. The system of claim 25, wherein a peripheral surface of the second roller includes a plurality of cells to retain the polymer mix therein.

27. The system of claim 25, further comprising:
a fourth roller disposed between the second roller and the third roller to transfer the polymer mix from the second roller onto the fourth roller and then onto the base film,
wherein the fourth roller includes a plurality of microscale features, which correspond to the plurality of polishing structures to be formed on the polishing pad.
